(19) United States
(12) Patent Application Publication
(10) Pub. No.: US 2020/0105842 A1
(43) Pub. Date: Apr. 2, 2020

(54) DISPLAY SUBSTRATE, MANUFACTURING METHOD THEREOF, ADJUSTMENT METHOD AND DISPLAY DEVICE

(71) Applicants: Hefei Xinsheng Optoelectronics Technology Co., Ltd., Hefei (CN); BOE TECHNOLOGY GROUP CO., LTD., Beijing (CN)

(72) Inventors: Zhongsheng QI, Beijing (CN); Mengyu LUAN, Beijing (CN)

(21) Appl. No.: 16/550,135

(22) Filed: Aug. 23, 2019

(30) Foreign Application Priority Data
Sep. 28, 2018 (CN) 201811142814.3

(51) Int. Cl. H01L 27/32; G02F 1/155; G02F 1/163; G02F 1/157

(52) U.S. Cl. CPC H01L 27/3232; G02F 1/155; H01L 27/3244; G02F 1/157; G02F 1/163

(57) ABSTRACT

A display substrate includes a base plate including an aperture area and a non-aperture area; a reflective layer and a transmittance adjustment film layer stacked on the non-aperture area of the base plate stacked on the non-aperture area of the base plate; wherein the transmittance adjustment film layer is configured to adjust a transmittance of a light incident to the transmittance adjustment film layer.

The present application claims priority to Chinese Patent Application No. 201811142814.3 and filed Sep. 28, 2018, the entire contents of which are incorporated herein by reference.

### TECHNICAL FIELD

The present disclosure relates to the field of display technology and, more particularly, to a display substrate, a manufacturing method thereof, an adjustment method, and a display device.

### BACKGROUND

The multi-functionality of the display device is an important direction for the development of the display industry presently, and a sound emitting screen, a transparent display, a mirror display, and the like are all multifunctional display panels. The mirror display can have a mirror effect while functions as a display screen so that the home entertainment functions, such as games, DVD movie playback, DV image editing, or digital camera image processing, and the like, can achieve a more perfect display effect.

The existing mirror screen generally produces a reflective layer in the display screen to reflect the outside light. Performance of the mirror screen still needs to be improved.

It is to be noted that the above information disclosed in this Background section is only for enhancement of understanding of the background of the present disclosure, and therefore, it may contain information that does not form the prior art that is already known to a person of ordinary skill in the art.

### SUMMARY

The present disclosure provides a display substrate, including:

a base plate including an aperture area and a non-aperture area; and

a reflective layer and a transmittance adjustment film layer stacked on the non-aperture area of the base plate, the stacked on the non-aperture area of the base plate;

wherein the transmittance adjustment film layer is configured to adjust a transmittance of a light incident to the transmittance adjustment film layer.

In an exemplary embodiment, the substrate includes:

a base substrate, and a pixel electrode layer and a pixel defining layer patterned on the base substrate;

an organic material layer and a cathode layer stacked on the pixel electrode layer, the organic material layer being disposed closer to the pixel electrode layer; and

an encapsulation layer covering the cathode layer and the pixel defining layer.

In an exemplary embodiment, the material of the encapsulation layer is an inorganic thin film material or an organic-inorganic composite thin film material.

In an exemplary embodiment, the material of the transmittance adjustment film layer is an electrochromic material.

In an exemplary embodiment, the material of the reflective layer is metal, and the display substrate further includes a transparent electrode on a side of the transmittance adjustment film layer facing away from the base plate.

In an exemplary embodiment, the electrochromic material includes at least one of the following: a transition metal oxide, a Prussian blue, a viologen molecule, and a conductive polymer.

The present disclosure provides a display device including the display substrate according to any one of the above embodiments.

The present disclosure provides an adjustment method of a display substrate, which is applied to the display substrate according to any one of the above embodiments, wherein the adjustment method includes:

adjusting a transmittance of the transmittance adjustment film layer, including: adjusting the light transmittance of the transmittance adjustment film layer to be higher than a first preset threshold value in a mirror display stage; and adjusting the light transmittance of the transmittance adjustment film layer to be lower than a second preset threshold value in a screen display stage,

wherein the first preset threshold value is larger than the second preset threshold value.

In an exemplary embodiment, when the material of the transmittance adjustment film layer is an electrochromic material, the material of the reflective layer is a metal, and the display substrate further includes a transparent electrode, the step of adjusting the light transmittance of the transmittance adjustment film layer includes:

changing a voltage difference applied between the reflective layer and the transparent electrode to adjust the light transmittance of the transmittance adjustment film layer.

In an exemplary embodiment, the voltage difference is greater than or equal to 1 V and less than or equal to 3 V.

The present disclosure provides a manufacturing method of a display substrate, including:

providing a base plate including an aperture area and a non-aperture area; and

forming a reflective layer and a transmittance adjustment film layer on the non-aperture area of the base plate,

wherein the transmittance adjustment film layer is configured to adjust a transmittance of a light incident to the transmittance adjustment film layer.

In an exemplary embodiment, the material of the transmittance adjustment film layer is an electrochromic material.

In an exemplary embodiment, the material of the reflective layer is metal, and the manufacturing method further includes:

forming a transparent electrode on a side of the transmittance adjustment film layer facing away from the base plate.

### BRIEF DESCRIPTION OF THE DRAWINGS

In order to more clearly illustrate the technical solutions of the embodiments of the present disclosure, the drawings used in the description of the embodiments of the present disclosure will be briefly described below. It should be noted that the drawings in the following description are only some embodiments of the present disclosure. Other drawings may also be obtained from these drawings by those of ordinary skill in the art based on these drawings without creative labor.

FIG. 1 is a cross-sectional structural diagram showing a display substrate according to an embodiment of the present application;

FIG. 2 is a cross-sectional structural diagram of a substrate according to an embodiment of the present application;

FIG. 3 is a cross-sectional structural diagram showing a display substrate according to another embodiment of the present application; and

FIG. 4 is a flow chart showing steps of a method for manufacturing a display substrate according to an embodiment of the present application.

### DETAILED DESCRIPTION

In order to make the above objects, features, and advantages of the present disclosure more apparent, the present disclosure will be further described in detail with reference to the accompanying drawings and specific embodiments.

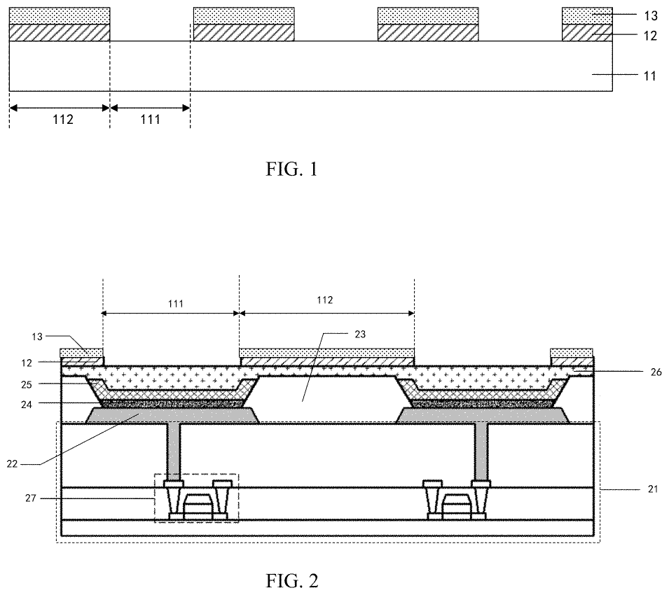

An embodiment of the present application provides a display substrate. Referring to FIG. 1, the display substrate may include a base plate 11 including an aperture area 111 and a non-aperture area 112; a reflective layer 12 and a transmittance adjustment film layer 13 stacked on the non-aperture area 112 of the base plate 11, the reflective layer 12 being disposed closer to the base plate 11, where the transmittance adjustment film layer 13 is configured to adjust a transmittance of a light incident to the transmittance adjustment film layer 13.

The principle of the mirror display is to reflect the ambient light by providing the reflective layer 12 in the non-aperture area 112, thereby improving the reflectance of the entire panel. The reflective layer 12 may be any reflective material, such as a metal, where the metal can include silver, magnesium, or a metal alloy.

The material of the transmittance adjustment film layer 13 may be any material having an adjustable light transmittance, for example, an organic or inorganic material, such as an electroluminescence material. The specific material of the transmittance adjustment film layer 13 is not limited in the present application.

In the display substrate provided in this embodiment, when a display screen is not required, the transmittance adjustment film layer 13 can be adjusted to have a high light transmittance, so that the amount of light reflected by the reflective layer 12 after being incident on the reflective layer 12 can be increased. The reflectance of the display substrate is high, and the mirror display is maintained. At this time, the contrast between the aperture area 111 and the non-aperture area 112 is low. When a display screen is required, it is desirable to reduce the reflectance of the display substrate, and the transmittance adjustment film layer 13 is in a state in which the light transmittance is low, so that the amount of light reflected by the reflective layer 12 after being incident on the reflective layer 12 can be reduced. The reflectance of the display substrate is low, and the screen display is maintained. Correspondingly, the contrast between the aperture area 111 and the non-aperture area 112 is high. Therefore, the display substrate provided in this embodiment can flexibly adjust the reflectance of the display substrate according to actual needs. On one hand, the conversion between the mirror display and the non-mirror display (i.e., the screen display) can be realized. On the other hand, the contrast between the aperture area 111 and the non-aperture area 112 can be adjusted, to provide a better display effect.

In one implementation, referring to FIG. 2, the base plate 11, described above, may include a base substrate 21, a pixel electrode layer 22, and a pixel defining layer 23 patterned on the base substrate 21; an organic material layer 24 and a cathode layer 25 stacked on the pixel electrode layer 22, the organic material layer 24 being disposed closer to the pixel electrode layer 22; and an encapsulation layer 26 covering the cathode layer 25 and the pixel defining layer 23.

The material of the encapsulation layer 26 may be an inorganic thin film material or an organic-inorganic composite thin film material. Thus, it is entirely feasible to fabricate the reflective layer 12 and the transmittance adjustment film layer 13 on the basis of the encapsulation layer 26.

In practical application, the base substrate 21 may include a plurality of thin film transistors 27, wherein the pixel electrode layer 22 is connected to the source and drain electrodes of the thin film transistor 27 through a via hole.

In another embodiment, the material of the transmittance adjustment film layer 13 is an electrochromic material. Electrochromism refers to a phenomenon in which the optical properties (reflectance, light transmittance, absorptivity, etc.) of a material may undergo a stable and reversible change under action of an applied electric field, and a reversible change in color or light transmittance may occur in appearance. The principle is that an electrochemical redox reaction occurs under the action of an applied electric field, and electrons are lost and recovered, so that the color or transmittance of the material changes.

The electrochromic material may include at least one of the following: a transition metal oxide, a Prussian blue, a violet molecule, a conductive polymer (such as polythiophene, polypyrrole, polyaniline, polyfluorene, etc.). These electrochromic materials have a good electrochemical redox process and can undergo a stable and reversible redox reaction during the incorporation and extraction of ions, ensuring stable color or transmittance changes. They also can achieve rich color change or transmittance change under different voltages, and the change process can be completed in tens of milliseconds to hundreds of milliseconds.

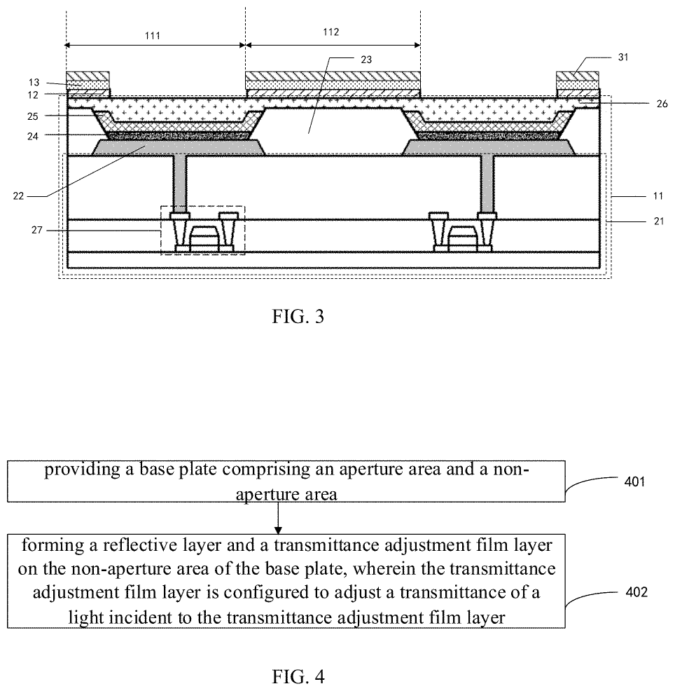

In order to form an applied electric field on the electrochromic material, referring to FIG. 3, the material of the reflective layer 12 may be metal, and any of the display substrates further includes a transparent electrode 31 on the side of the transmittance adjustment film layer 13 facing away from the base plate 11.

In this way, the reflective layer can serve as the first electrode, and by adjusting the voltage difference between the first electrode and the transparent electrode 31, the magnitude of the electric field acting on the electrochromic material can be adjusted, thereby adjusting the light transmittance of the electrochromic material. The voltage difference can be, for example, greater than or equal to 1V and less than or equal to 3V.

When a display screen is not required, the voltage difference between the first electrode and the transparent electrode 31 can be adjusted to make the electrochromic material in a state of high transmittance, so that the amount of light reflected by the reflective layer 12 after being incident on the reflective layer 12 can be increased. The reflectance of the display substrate is high, and the mirror display is maintained. At this time, the contrast between the aperture area 111 and the non-aperture area 112 is low. When a display screen is required, it is desirable to reduce the reflectance of the display substrate, and the voltage difference between the first electrode and the transparent electrode 31 can be adjusted to make the electrochromic material in a state of low transmittance, so that the amount of light reflected by the reflective layer 12 after being incident on the reflective layer 12 can be reduced. The reflectance of the display substrate is low, and the screen display is maintained. Correspondingly, the contrast between the aperture area 111 and the non-aperture area 112 is high. Therefore, in the display substrate provided in this embodiment, the reflectance of the display substrate and the contrast of the aperture area 111 and the non-aperture area 112 can be changed to improve the display effect through the control of electrochromic material.

The reflective layer and the transparent electrode 31 as the first electrode may be formed on the encapsulation layer 26 by magnetron sputtering, thermal reaction evaporation, electron beam evaporation, or the like.

It should be noted that there are many ways to form an applied electric field on the electrochromic material, and it is not limited to applying voltage difference between the reflective layer and the transparent electrode, and the means for applying an external electric field on the electrochromic material is not specifically limited in this embodiment.

Another embodiment of the present application further provides a display device, which may include the display substrate described in any of the above embodiments.

It should be noted that the display device in this embodiment may be any product or component having a display function, such as a display panel, an electronic paper, a mobile phone, a tablet computer, a television, a notebook computer, a digital photo frame, a navigator, and the like.

Another embodiment of the present application further provides a method for adjusting a display substrate, which is applied to the display substrate according to any of the above embodiments. The adjustment method may include the following solutions.

Adjusting the light transmittance of the transmittance adjustment film layer includes: adjusting the light transmittance of the transmittance adjustment film layer to be higher than a first preset threshold value in a mirror display stage; and adjusting the light transmittance of the transmittance adjustment film layer to be lower than a second preset threshold value in a screen display stage. The first preset threshold value is larger than the second preset threshold value.

The first preset threshold may be greater than or equal to 50%, such as 80%, 90%, etc.; the second predetermined threshold may be less than or equal to 50%, such as 20%, 10%, and the like.

In this embodiment, by adjusting the transmittance of the transmittance adjustment film layer and changing the amount of reflected light of the reflective layer, the reflectance of the display substrate can be flexibly adjusted. On one hand, the conversion between the mirror display and the non-mirror display can be realized and, on the other hand, it can flexibly adjust the contrast between the aperture area and the non-aperture area and improve the display effect.

When the material of the transmittance adjustment film layer is an electrochromic material, the material of the reflective layer is a metal, and the display substrate further includes a transparent electrode, the step of adjusting the light transmittance of the transmittance adjustment film layer may include:

changing the voltage difference applied between the reflective layer and the transparent electrode to adjust the light transmittance of the transmittance adjustment film layer.

The voltage difference applied between the reflective layer and the transparent electrode may be greater than or equal to 1V and less than or equal to 3V. The specific voltage difference can be determined according to the electrochromic material and the actual effect, which is not specifically limited in the present application.

For the adjustment process and principle of the display substrate in this embodiment, reference may be made to the description of the foregoing embodiments, details of which will not be repeated herein.

Another embodiment of the present application further provides a method for manufacturing a display substrate. Referring to FIG. 4, the manufacturing method may include the following steps.

In Step 401: a base plate is provided, the base plate including an aperture area and a non-aperture area.

In Step 402, a reflective layer and a transmittance adjustment film layer are sequentially formed on the non-aperture area of the base plate, wherein the transmittance adjustment film layer is configured to adjust a transmittance of a light incident to the transmittance adjustment film layer. A cross-sectional view of a display substrate made up of a reflective layer and a transmittance adjustment film layer is shown in FIG. 1.

In an implementation, Step 401 may further include the following steps.

In Step 501, a substrate is provided.

In Step 502, a pixel electrode layer and a pixel defining layer are patterned on the substrate.

In Step 503, an organic material layer and a cathode layer are sequentially formed on the pixel electrode layer.

In Step 504, an encapsulation layer is formed on the cathode layer and the pixel defining layer to obtain the base plate. The structure of the base plate is shown in FIG. 2, in which the pixel electrode layer corresponds to the aperture area, and the pixel defining layer corresponds to the non-aperture area.

The material of the encapsulation layer is an inorganic thin film material or an organic-inorganic composite thin film material.

In another embodiment, when the material of the transmittance adjustment film layer may be an electrochromic material, and the material of the reflective layer is a metal, the manufacturing method may further include the following step.

In Step 403, a transparent electrode is formed on the side of the transmittance adjustment film layer facing away from the base plate. A cross-sectional view of the display substrate in which the transparent electrode is completed is shown in FIG. 3.

The reflective layer and the transparent electrode as the first electrode may be formed on the encapsulation layer by magnetron sputtering, thermal reaction evaporation, electron beam evaporation, or the like.

The embodiments of the present application provide a display substrate, a manufacturing method thereof, an adjustment method, and a display device. The display substrate includes: a base plate including an aperture area and a non-aperture area, a reflective layer and a transmittance adjustment film layer stacked on the non-aperture area of the base plate, the reflective layer being disposed closer to the base plate 11, wherein the transmittance adjustment film layer is configured to adjust a transmittance of a light incident to the transmittance adjustment film layer. In the technical solution of the present application, the light transmittance of the incident light is adjusted by the transmittance adjustment film layer and changes the amount of the reflected light of the reflective layer, thereby flexibly adjusting the reflectance of the display substrate. On the other hand, it can realize the conversion between the mirror display and the non-mirror display, and on the other hand, the contrast between the aperture area and the non-aperture area can be flexibly adjusted to improve the display effect.

The various embodiments in the present specification are described in a progressive manner, and each embodiment focuses on differences from other embodiments, and the same similar parts between the various embodiments can be referred to each other.

Finally, it should also be noted that in this context, relational terms, such as first and second, are used merely to distinguish one entity or operation from another entity or operation and do not necessarily require or imply that there is any such actual relationship or order between these entities and operations. Furthermore, the terms “include” or “contain” or any other variations are intended to encompass a non-exclusive inclusion, such that a process, method, article, or device that includes a series of elements includes not only those elements but also other elements not explicitly listed, or elements that are inherent to the process, method, article, or device. An element defined by the phrase “comprising a . . . ” does not exclude the presence of additional equivalent elements in the process, method, item, or device including the element.

The display substrate, the manufacturing method thereof, the adjustment method, and the display device provided by the present disclosure are described in detail. The principle and the embodiments of the present disclosure are described with reference to specific examples. The description of the above embodiments is only used to help understand the method of the present disclosure and its core idea. Moreover, for those skilled in the art, according to the idea of the present disclosure, there may be variations in the specific embodiments and the scope of application. The contents of this specification are not to be construed as limiting the present disclosure.

What is claimed is:

1. A display substrate, comprising:
a base plate comprising an aperture area and a non-aperture area; and
a reflective layer and a transmittance adjustment film layer stacked on the non-aperture area of the base plate, the reflective layer being disposed closer to the base plate;
wherein the transmittance adjustment film layer is configured to adjust a transmittance of a light incident to the transmittance adjustment film layer.

2. The display substrate according to claim 1, wherein the base plate comprises:
a base substrate, and a pixel electrode layer and a pixel defining layer patterned on the base substrate;
an organic material layer and a cathode layer stacked on the pixel electrode layer, the organic material layer being disposed closer to the pixel electrode layer; and
an encapsulation layer covering the cathode layer and the pixel defining layer.

3. The display substrate according to claim 2, wherein a material of the encapsulation layer is an inorganic thin film material or an organic-inorganic composite thin film material.

4. The display substrate according to claim 1, wherein a material of the transmittance adjustment film layer is an electrochromic material.

5. The display substrate according to claim 2, wherein a material of the transmittance adjustment film layer is an electrochromic material.

6. The display substrate according to claim 3, wherein a material of the transmittance adjustment film layer is an electrochromic material.

7. The display substrate according to claim 4, wherein a material of the reflective layer is a metal, and the display substrate further comprises a transparent electrode on a side of the transmittance adjustment film layer facing away from the base plate.

8. The display substrate according to claim 4, wherein the electrochromic material comprises at least one of the following: a transition metal oxide, a Prussian blue, a viologen molecule, and a conductive polymer.

9. A display device comprising the display substrate according to claim 1.

10. A display device comprising the display substrate according to claim 2.

11. A display device comprising the display substrate according to claim 3.

12. A display device comprising the display substrate according to claim 4.

13. A display device comprising the display substrate according to claim 7.

14. A display device comprising the display substrate according to claim 8.

15. An adjustment method of a display substrate, which is applied to the display substrate comprising an aperture area and a non-aperture area; and a reflective layer and a transmittance adjustment film layer stacked on the non-aperture area of a base plate, the reflective layer being disposed closer to the base plate, the transmittance adjustment film layer being configured to adjust a transmittance of a light incident to the transmittance adjustment film layer;
wherein the adjustment method comprises:
adjusting the transmittance of the transmittance adjustment film layer, comprising: adjusting a light transmittance of the transmittance adjustment film layer to be higher than a first preset threshold value in a mirror display stage; and adjusting the light transmittance of the transmittance adjustment film layer to be lower than a second preset threshold value in a screen display stage,
wherein the first preset threshold value is larger than the second preset threshold value.

16. The adjustment method of the display substrate according to claim 15, wherein when a material of the transmittance adjustment film layer is an electrochromic material, the material of the reflective layer is a metal, and the display substrate further comprises a transparent electrode, a step of adjusting the light transmittance of the transmittance adjustment film layer comprises:
changing a voltage difference applied between the reflective layer and the transparent electrode to adjust the light transmittance of the transmittance adjustment film layer.

17. The adjustment method of the display substrate according to claim 16, wherein the voltage difference is greater than or equal to 1 V and less than or equal to 3 V.

18. A manufacturing method of a display substrate, comprising:
providing a base plate comprising an aperture area and a non-aperture area; and
forming a reflective layer and a transmittance adjustment film layer on the non-aperture area of the base plate,
wherein the transmittance adjustment film layer is configured to adjust a transmittance of a light incident to the transmittance adjustment film layer.

19. The manufacturing method according to claim 18, wherein a material of the transmittance adjustment film layer is an electrochromic material.

20. The manufacturing method according to claim 19, wherein the material of the reflective layer is a metal, and the manufacturing method further comprises:
forming a transparent electrode on a side of the transmittance adjustment film layer facing away from the base plate.
